(19) United States
(12) Patent Application Publication
(10) Pub. No.: US 2009/0226823 A1
(43) Pub. Date: Sep. 10, 2009

(54) RETICLES INCLUDING ASSISTANT STRUCTURES, METHODS OF FORMING SUCH RETICLES, AND METHODS OF UTILIZING SUCH RETICLES

(75) Inventors: William A. Stanton, Boise, ID (US); Fei Wang, Boise, ID (US)

Correspondence Address: TRASK BRITT, P.C./ MICRON TECHNOLOGY, P.O. BOX 2550, SALT LAKE CITY, UT, 84110, US

(73) Assignee: MICRON TECHNOLOGY, INC., Boise, ID (US)

(21) Appl. No.: 12/043,447

(22) Filed: Mar. 6, 2008

(51) Int. Cl. G03F 1/00; G03F 7/00

(52) U.S. Cl. 430/5; 430/319

(57) ABSTRACT

Reticles comprising assistant structures in contact with at least sidewalls of a phase shift and transmission control material are disclosed. The assistant structures are formed from an absorptive material, such as chromium. The assistant structures provide reduced scumming defects in features produced using the reticles. Methods of forming the reticles and methods of utilizing the reticles are also disclosed.

### TECHNICAL FIELD

Embodiments of the invention relate to fabricating semiconductor structures and, more specifically, to preventing scumming defects on semiconductor structures.

### BACKGROUND

Step and repeat lithographic devices, called scanners or wafer steppers, are commonly used to mass produce semiconductor devices, such as integrated circuits (ICs). Typically, an illumination source and various lenses are used to project an image of a reticle onto a photosensitive coating of a semiconductor substrate. The projected image of the reticle imparts a corresponding pattern on the photosensitive coating. This pattern may be used to selectively etch or deposit material to form desired features on the semiconductor substrate. Of course, it is desirable to have very sharp features formed. For example, when forming a trench, there should be no unintended photosensitive material left in the trench. However, at times, some portions of the feature may not be formed correctly. When forming a trench, sometimes all of the photosensitive material that was intended to be removed is not completely removed, causing defects. The unremoved photosensitive material or defect is sometimes referred to as scumming.

A trench having unremoved photosensitive material therein may hinder performance of a device formed from the semiconductor substrate. For example, if the formed trench is to be filled with conductive material, the unremoved photosensitive material decreases the size of a conductor formed from the conductive material. When considering the small size of such features, the unremoved photosensitive material may reduce the performance of the conductor and the device formed therefrom. In an extreme case, the formed device may fail. This problem may be more pronounced in the future as the dimensions of these devices become smaller.

Accordingly, what is needed in the art are reticles and methods of suppressing scumming defects in features formed on a semiconductor substrate.

### BRIEF DESCRIPTION OF THE SEVERAL VIEWS OF THE DRAWINGS

FIGS. 1A-1D are cross-sectional views of reticles having assistant structures in accordance with embodiments of the invention;

FIGS. 2A-2G are cross-sectional views illustrating the fabrication of the reticles of FIGS. 1A and 1B;

FIGS. 3A-3M are cross-sectional views illustrating the fabrication of the reticles of FIGS. 1C and 1D;

FIG. 4 is a schematic drawing illustrating use of a reticle in accordance with an embodiment of the invention to form features on a semiconductor substrate;

FIG. 5 is a graph illustrating changes in light intensity versus width of an isolated trench formed using a control reticle; and

FIGS. 6 and 7 are graphs illustrating changes in light intensity versus width of isolated trenches formed using reticles in accordance with embodiments of the invention.

### DETAILED DESCRIPTION OF THE INVENTION

Embodiments described herein provide reticles and methods of using such reticles to form features having reduced scumming on a semiconductor substrate. Reticles having at least one assistant structure are used to form the features on the semiconductor substrate. As used herein, the term “reticle” means and includes a fully-formed reticle (i.e., a reticle ready for use in a photolithography process) or a partially-formed reticle at any stage in the process of forming the reticle.

The following description provides specific details, such as material types and fabrication techniques, in order to provide a thorough description of embodiments of the invention. However, a person of ordinary skill in the art will understand that these and other embodiments of the invention may be practiced without employing these specific details. Indeed, embodiments of the invention may be practiced in conjunction with additional materials and fabrication techniques employed in the industry. In addition, the description provided below does not form a complete process flow for manufacturing a semiconductor device utilizing the reticles. Only those process acts necessary or desirable to understand the embodiments of the invention are described in detail below. Additional acts to form the semiconductor device may be performed by conventional fabrication techniques, which are, therefore, not described herein.

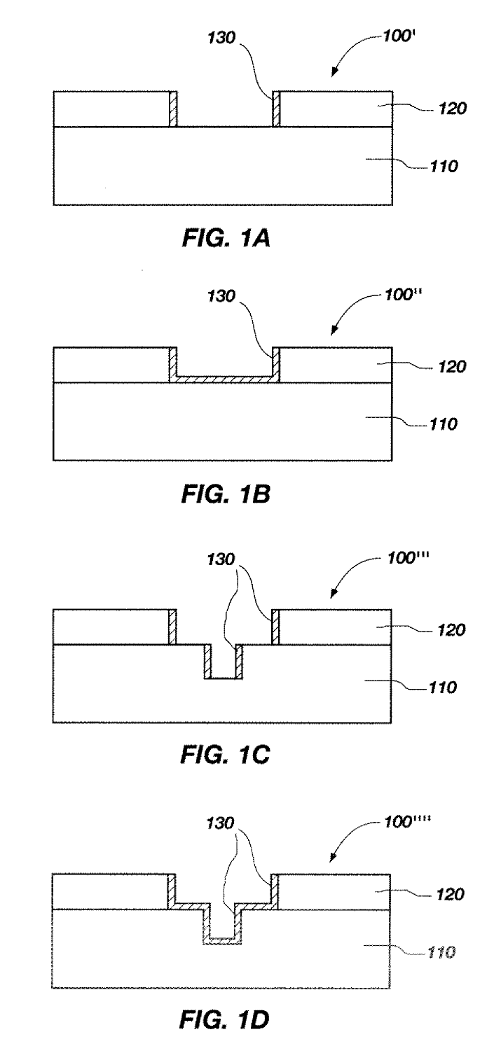

As shown in FIGS. 1A-1D, the reticle 100′, 100″, 100′″, 100″″ includes an optically transparent material 110, a phase shift and transmission control material 120, and assistant structure 130. The assistant structure 130 may be in contact with the phase shift and transmission control material 120, or in contact with both the optically transparent material 110 and the phase shift and transmission control material 120. For convenience, the term “reticle 100” is used herein to collectively refer to reticle 100′, reticle 100″, reticle 10′″, and reticle 100″″. The term “reticle 100′,” “reticle 100″,” “reticle 100′″,” or “reticle 100″″” is used herein to refer to a specific reticle. The optically transparent material 110 and the phase shift and transmission control material 120 may be in direct contact with one another, forming a horizontal interface therebetween. Alternatively, the optically transparent material 110 and the phase shift and transmission control material 120 may be separated by additional materials, as may be contemplated in certain embodiments.

In one embodiment, the assistant structure 130 at least partially lines exposed surfaces of the phase shift and transmission control material 120, as shown in FIGS. 1A and 1B. The assistant structure 130 may be present on sidewalls of the phase shift and transmission control material 120 to form reticle 100′, or on sidewalls of the phase shift and transmission control material 120 and on an exposed horizontal edge of the optically transparent material 110 to form reticle 100″. In another embodiment, the assistant structure 130 at least partially lines exposed surfaces of the phase shift and transmission control material 120 and exposed surfaces of the optically transparent material 110. The assistant structure 130 may be present on sidewalls of the phase shift and transmission control material 120 and of the optically transparent material 110 to form reticle 100′″, or on sidewalls of the phase shift and transmission control material 120 and the optically transparent material 110 and on exposed horizontal edges of the optically transparent material 10 to form reticle 100″″.

The optically transparent material 110 may be a semi-transparent material formed of quartz, fluorinated quartz, CaF₂, or hafnium oxide. The thickness of the optically transparent material 10 may be from approximately 0.1 cm to approximately 5 cm. In one embodiment, the optically transparent material 110 is a conventional quartz plate having a thickness of between approximately 0.125 inches (0.32 cm) and approximately 0.25 inches (0.65 cm), e.g., approximately 0.25 inch (6.35 mm). The phase shift and transmission control layer 120 may be a metal-doped silicon, such as molybdenum silicon (MoSi), molybdenum-doped silicon oxide (MoSiₓO_{y}), molybdenum-doped silicon oxynitride (MoSiₓO_{y}N_{z}), molybdenum-doped silicon nitride, molybdenum silicide, or combinations thereof wherein “x”, “y” and “z” are numbers greater than zero. Alternatively, the phase shift and transmission control layer 120 may be tantalum hafnium (TaₓHf_{y}), tantalum nitride (TaₓN_{y}) and silicon oxynitride (SiOₓN_{y}), wherein “x”, “y” and “z” are numbers greater than zero. The thickness of the phase shift and transmission control layer 120 may depend on the wavelength of light intended for use with the reticle 100. By way of non-limiting example, the thickness of the phase shift and transmission control layer 120 may be from approximately 50 nm to approximately 100 nm if a wavelength of from approximately 193 nm to approximately 248 nm is used.

The materials used as the optically transparent material 110 and the phase shift and transmission control layer 120 may be selected based on the wavelength of light to which the reticle 100 is exposed. For instance, the reticle 100 may be utilized with 157 nm radiation, 193 nm radiation, 248 nm radiation, or 365 nm radiation. By way of non-limiting example, if the reticle 100 is to be used with 193 nm radiation, quartz may be used as the optically transparent material 110 and MoSi may be used as the phase shift and transmission control layer 120.

The assistant structure 130 may be formed from a material that is optically opaque to, and absorptive of, the wavelength of radiation to which the reticle 100 is exposed. As used herein, the term “absorptive,” or grammatical equivalents thereof, means and includes intercepting the radiation or light to which the reticle 100 is exposed. Accordingly, the radiation may not substantially pass through the assistant structure 130 of the reticle 100. The material of the assistant structure 130 may also be capable of being formed by a conformal deposition technique. By way of non-limiting example, the assistant structure 130 may be formed from a metal material including, but not limited to, chromium (Cr), a chromium-containing compound, titanium nitride, tungsten, or combinations thereof. In one embodiment, the assistant structure 130 is formed from chromium. The assistant structure 130 may have a thickness between approximately 10 nm and approximately 40 nm.

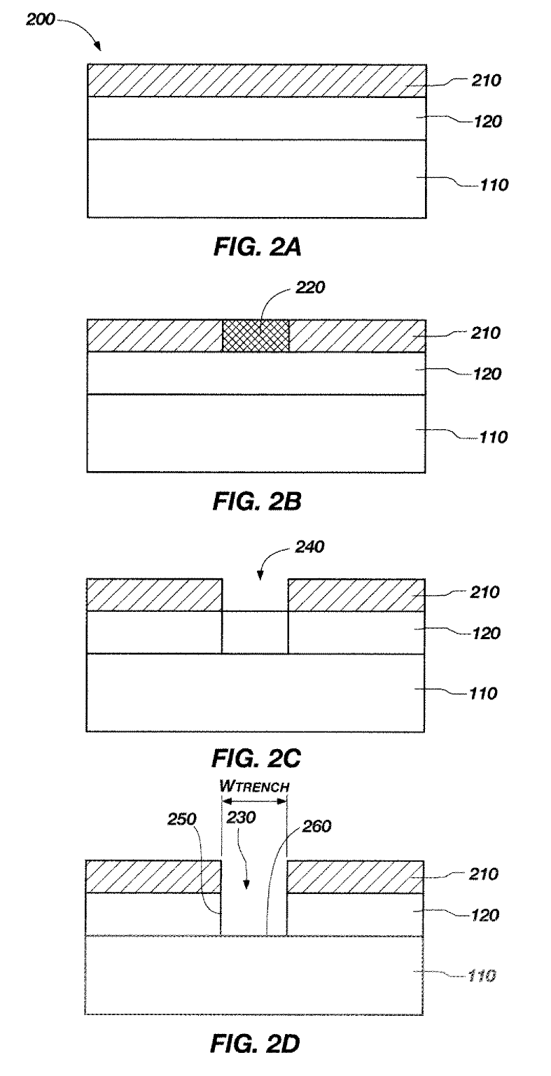

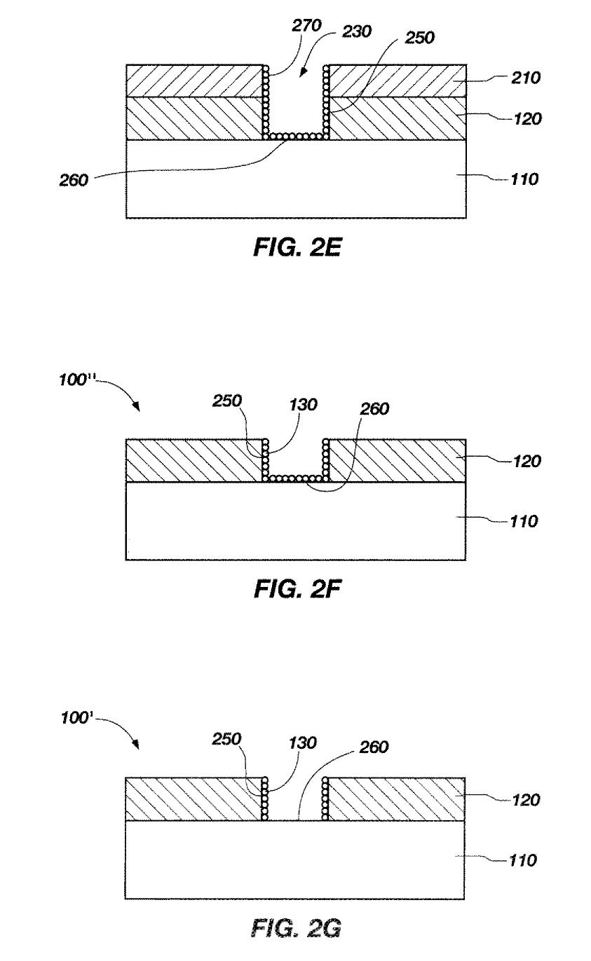

To form the reticles 100′, 100″, a reticle substructure 20 including a photodefinable material 210, optically transparent material 110, and phase shift and transmission control layer 120 is formed, as shown in FIG. 2A. While photodefinable material 210, optically transparent material 110, and phase shift and transmission control material 120 are illustrated as layers, other three-dimensional configurations of the materials may be used. The phase shift and transmission control material 120 may be formed on the optically transparent material 110 by conventional techniques, which are not described in detail herein. The photodefinable material 210 may be a photoresist material formed on the phase shift and transmission control layer 120 by any suitable technique. By way of non-limiting example, the photodefinable material 210 may be “RISTON,” manufactured by DuPont de Nemours Chemical Company. The photodefinable material 210 maybe disposed on the phase shift and transmission control layer 120 at a thickness between approximately 200 nm and approximately 600 nm.

The photodefinable material 210 may be patterned to form patterned area 220, as shown in FIG. 2B. The patterned area 220 may be formed by conventional techniques, such as by photolithography, electron beam (e-beam) lithography, or e-beam writing. The width of patterned area 220 corresponds to approximately the width of a gap 230 or trench ultimately to be formed in the phase shift and transmission control layer 120 (see FIG. 2D). The patterned area 220 may be developed and etched to form opening 240 in the photodefinable material 210, as shown in FIG. 2C. The patterned area 220 may be developed and etched by conventional techniques, which are not described herein.

The opening 240 in the photodefinable material 210 lay then be transferred into the phase shift and transmission control material 120, forming a gap 230, as shown in FIG. 2D. The gap 230 may be formed by etching the phase shift and transmission control material 120 using the opening 240 as a mask. Etch chemistries and etch conditions for forming the gap 230 may be selected by a person of ordinary skill in the art based on the material used as the phase shift and transmission control material 120 and, therefore, are not described in detail herein. By way of non-limiting example, if the phase shift and transmission control layer 120 is formed from MoSi, a SF₆ etch chemistry may be used. The gap 230 may be defined by sidewalls 250 of the phase shift and transmission control material 120 and horizontal edge 260 of the optically transparent material 110. The gap 230 defines a trench having width “W_{TRENCH},” which corresponds to the width of a trench or line ultimately to be formed in the semiconductor substrate. Since patterns in reticles 100 are typically four times the size of features to be formed in the semiconductor substrate, if the trench to be formed in the semiconductor substrate is less than or equal to approximately 300 nm, W_{TRENCH} may be less than or equal to approximately 1200 nm.

As shown in FIG. 2E, a thin, conformal layer of the metal material 270 may be formed on the sidewalls 50 and horizontal edge 260 of the gap 230. Deposition of the metal material 270 may be accomplished by atomic layer deposition (ALD) or other technique suitable for conformally depositing the metal material 270. The metal material 270 may be conformally deposited at a thickness of from approximately 10 nm to approximately 40 nm. The photodefinable material 210 may then be removed, forming the reticle 100″ having assistant structure 130, as shown in FIG. 2F. Etch chemistries and etch conditions for removing the photodefinable material 210 may be determined by a person of ordinary skill in the an depending on the material used. Accordingly, these etch chemistries and etch conditions are not described in detail herein. To form reticle 100′, the metal material 270 on the horizontal edge 260 of the optically transparent material 110 may be removed, as shown in FIG. 2G. Etch chemistries and etch conditions for selectively removing the metal material 270 may be determined by a person of ordinary skill in the art depending on the material used. Accordingly, these etch chemistries and etch conditions are not described in detail herein. By way of non-limiting example, if the metal material 270 is formed from chromium, Cl₂, O₂, or He may be used to remove portions of the metal material 270.

By way of non-limiting example, an anisotropic etch may be used to expose the horizontal edge 260 of optically transparent material 110 in the gap 230 without removing the metal material 270 from the sidewalls 250 of the gap 230. Therefore, in one embodiment, the reticle 100″ includes the assistant structure 130 on sidewalls 250 of the phase shift and transmission control material 120 and horizontal edge 260 of the optically transparent material 110. In another embodiment, the reticle 100′ includes the assistant structure 130 only on sidewalls 250 of the phase shift and transmission control material 120.

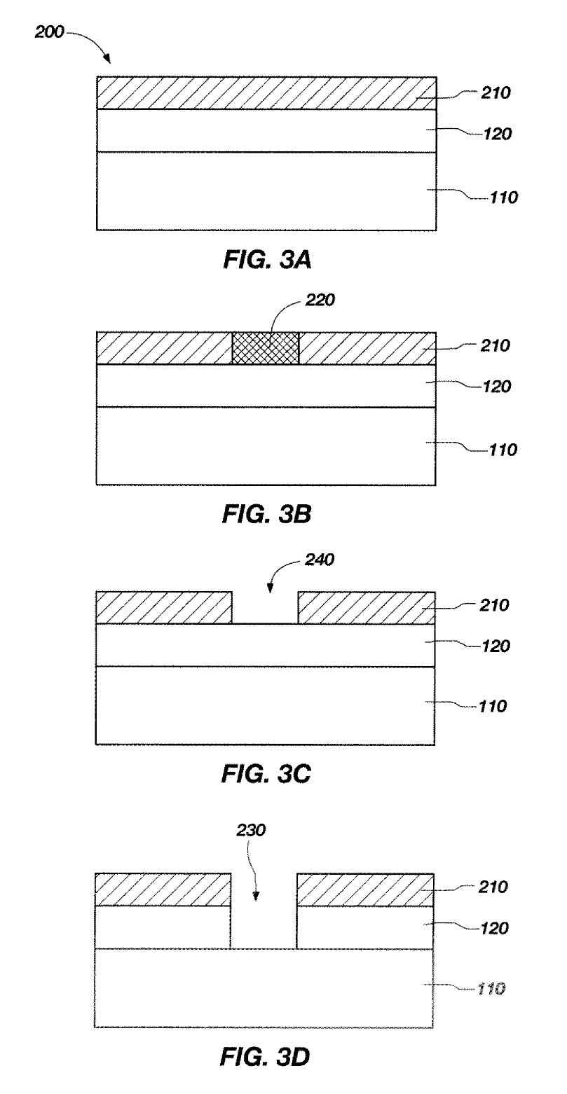

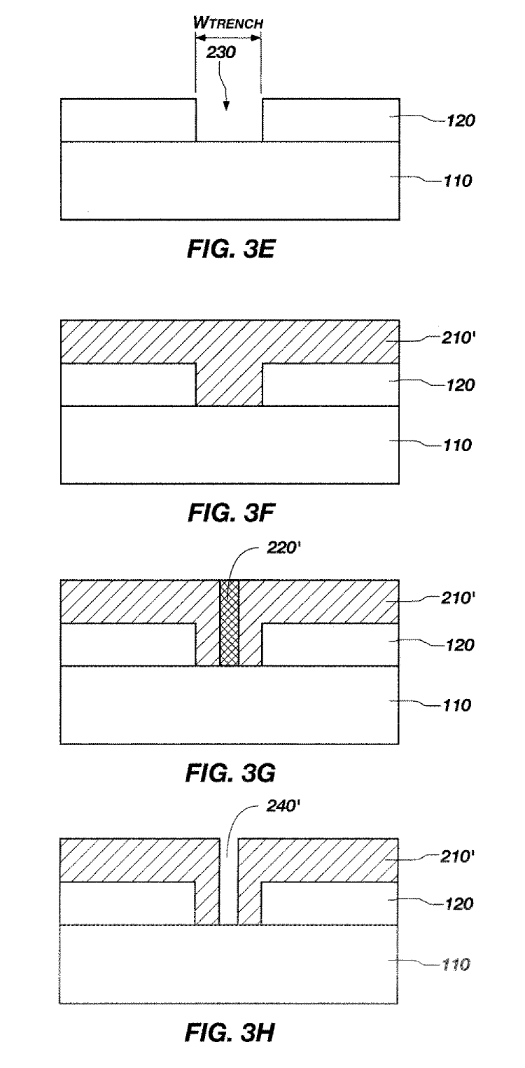

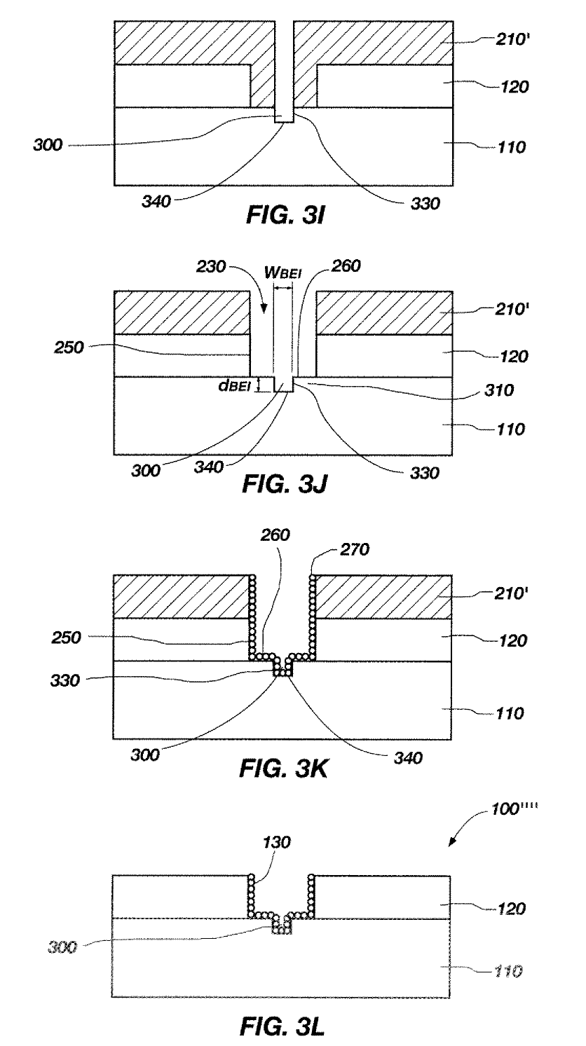

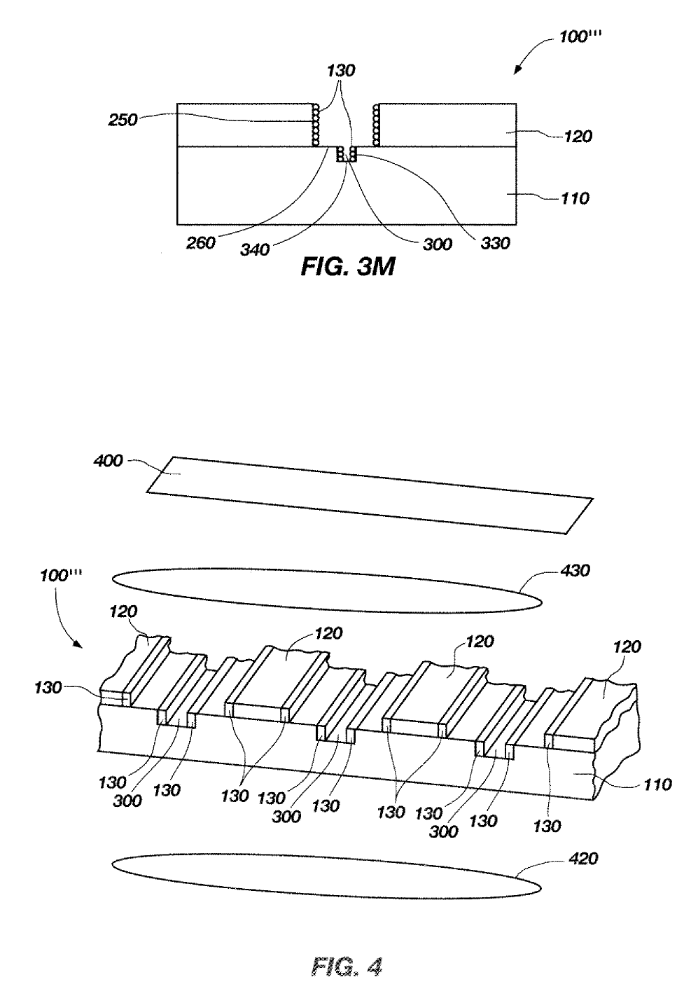

The reticles 100′″, 100″″ may be formed according to FIGS. 3A-3M. As shown in FIG. 3A, the reticle substructure 200 is formed as previously described. FIG. 3B shows formation of patterned area 220 in the photodefinable material 210. The patterned area 220 is formed as previously described. The width of patterned area 220 corresponds to approximately the width of gap 230 ultimately to be formed in the phase shift and transmission control material 120 (see FIG. 3D). The patterned area 220 may be developed and etched to form opening 240 in the photodefinable material 210, as shown in FIG. 3C. The opening 240 may be formed as described above. The opening 240 may then be transferred into the phase shift and transmission control material 120, forming the gap 230 therein, as shown in FIG. 3D. The gap in the phase shift and transmission control material 120 may be formed as described above. Remaining portions of the photodefinable material 210 may be removed, as shown in FIG. 3E. Another photodefinable material 210′ may be formed in the gap 230, as well as over the phase shift and transmission control material 120, as shown in FIG. 3F. As shown in FIGS. 3G and 3H, the photodefinable material 210′ may be patterned to form patterned area 220′ and developed to form an opening 240′ in the photodefinable material 210′. The photodefinable material 210′ may be patterned and developed by conventional techniques, which are not described in detail herein.

The width of the opening 240′ may correspond to the width of a back-etched inrigger (“BEI”) 300 or trench ultimately to be formed in the optically transparent material 110 (see FIG. 3I). The BEI 300 defines a trench having width “W_{BEI}” in the optically transparent material 110, which corresponds to the width of a trench or line ultimately to be formed in the semiconductor substrate. The opening 240′ may be used as a mask to etch the optically transparent material 110, forming the BEI 300, as shown in FIG. 3I. The BEI 300 is so named because it may be formed by etching into the optically transparent material 110. The BEI 300 may have sidewalls 330 and a bottom edge 340. By way of non-limiting example, if the optically transparent material 110 is formed from quartz, the BEI 300 may be formed using CF₄ to etch the optically transparent material 110. The BEI 300 may have a width indicated in FIG. 3J as “W_{BEI}” and a depth indicated as “d_{BEI}.” W_{BEI} may range from approximately 25% of W_{TRENCH} to approximately 50% W_{TRENCH}, more particularly from approximately 30% of W_{TRENCH} to approximately 35% of W_{TRENCH}. For instance, W_{BEI} may be approximately 33% of W_{TRENCH}. The BEI 300 in reticles 100′″, 100″″ may also be formed as described in U.S. patent application Ser. No. 11/670,887, filed on Feb. 2, 2007, the disclosure of which is incorporated by reference herein in its entirety.

The depth of the BEI 300 may be selected to achieve a desired phase shift of light passing through the reticle 100, according to the equation: (n−1)×(d)=(φ_{Δ})×(λ)×(M), where “n” is the refractive index of the optically transparent material 110, “λ” is the wavelength of light being used, and “M” is the magnification factor of a projection lens system used to form the feature on the semiconductor substrate. In the equation, “φ₆₆ ” is the fraction of phase shift in light passing through the BEI 300. For example, if a phase shift of −180° were desired, a value of ½ would be used for φ_{Δ}. Similarly, if a phase shift of −90° were desired, a value of ¼ would be used for φ_{Δ}. d_{BEI} may be equal to the difference in thickness of the optically transparent material 110 at the BEI 300 compared to the thickness at neutral regions 310. The depth of the BEI 300 may range from approximately 100 nm to approximately 1000 nm.

An anisotropic etch may be used to selectively remove portions of the photodefinable material 210′ remaining in the gap 230, exposing a horizontal edge 260 of the optically transparent material 110 without exposing a top surface of the phase shift and transmission control material 120, as shown in FIG. 3J. The portion of the optically transparent material 110 directly beneath the horizontal edge 260 corresponds to the neutral regions 310. The metal material 270 may be conformally formed on the sidewalls 250 of the phase shift and transmission control material 120, the sidewalls 330 of the BEI 300, the horizontal edge 260 of the optically transparent material 110, and the bottom edge 340 of the BEI 300, as shown in FIG. 3K. The metal material 270 may be formed as described above and may include one of the materials described above. The photodefinable material 210′ may then be removed to form the reticle 100″″ having assistant structure 130, as shown in FIG. 3L. Etch chemistries and etch conditions for removing the photodefinable material 210′ may be determined by a person of ordinary skill in the art depending on the material used. To form reticle 100′″ having assistant stricture 130, the metal material 270 on the horizontal edge 260 of the optically transparent material 110 and the bottom edge 340 of the BEI 300 may be removed, as shown in FIG. 3M. An anisotropic etch may be used to selectively remove the metal material 270. Etch chemistries and etch conditions for selectively removing the metal material 270 may be determined by a person of ordinary skill in the art depending on the material. As shown in FIGS. 3L and 3M, the BEI 300 lined with metal material 270 may be positioned in about the center of gap 230. The BEI 300 may include a region of reduced thickness, relative to other portions of the optically transparent material 110.

Each of the reticles 100 may be used to form at least one feature in a semiconductor substrate 400, as illustrated in FIG. 4. As used herein, the term “semiconductor substrate” means and includes a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, or indium phosphide. The feature may be, for example, a trench, such as an isolated trench. The isolated trench may have a width of between approximately 50 nm and approximately 500 nm. While FIG. 4 illustrates using reticle 100′″, reticle 100′, reticle 100″, or reticle 100″″ may be used in a similar manner to form the features in the semiconductor substrate 400. In addition, while the formation of isolated trenches is described herein, other features may be formed on the semiconductor substrate 400.

To form the isolated trenches, the reticle 100′″ may be disposed between an illumination source 420 and projection lens system 430. The illumination source 420 may be a circle dipole, quadropole, CQuad, or annular illumination source. In use and operation, light from the illumination source 420 passes through portions of the optically transparent material 110 before reaching the phase shift and transmission control material 120 and the assistant structure 130. However, the light does not pass through the phase shift and transmission control material 120 and the assistant structure 130. Rather, the assistant structure 130 absorbs at least a portion of the light, while the phase shift and transmission control material 120 shifts the phase and controls the transmission of light passing through the reticle 100′″. By way of non-limiting example, light passing through the phase shift and transmission control material 120 exits from 160° to 200° out of phase relative to light passing through regions of the optically transparent material 110. More particularly, the light exits from 175° to 185° out of phase relative to light passing through regions of the optically transparent material 110. As such, the phase shift and transmission control material 120 and the assistant structure 130 enable only a small portion of the light emitted by the illumination source 420, such as 20% or less, to pass through the reticle 100′″. Accordingly, the phase shift and transmission control material 120 and the assistant structure 130 form a so-called “dark field” of the reticle 100′″. The dark field is a portion of the reticle 100′″ that does not transmit a sufficient amount of light to chemically alter a photopatternable material (not shown) on the semiconductor substrate 400, at least not to the extent distinguishable by a development process of the photopatternable material. A so-called “clear field” of the reticle 100′″ is a portion that transmits sufficient light to chemically alter the photopatternable material on the semiconductor substrate 400. In the embodiment illustrated in FIG. 4, the clear field includes portions of the gap 230 and the BEI 300 that are not covered by the assistant structure 130. In other words, the clear field includes portions of the gap 230 and the BEI 300 remaining between adjacent portions of the assistant structure 130. Since the light passing through the clear field of the reticle 100′″ is of sufficient intensity to alter the photopatternable material, features formed on the semiconductor substrate 400 using the reticle 100′″ may have reduced scumming. Without being bound by any particular theory, it is believed that the assistant structure 130 on the reticle 110′″ improves the ability of the dark field to prevent light transmission therethrough. In other words, the assistant structure 130 absorbs light and makes the dark field of the reticle 100′″ darker. However, the light that passes through the clear field of the reticle 100″ remains above a threshold level for developing the photopatternable material on the semiconductor substrate 400. In addition, the difference in thickness of the optically transparent material 110 at the BEI 300 versus that at the neutral regions 310 serves to shift the phase of light passing through the BEI 300 relative to light passing through the neutral regions 310. Without being bound by any particular theory, it is believed that the phase shift reduces scumming because it provides a constructive imaging modulation where the BEI 300 is located.

The pattern of the reticle 100′″ may determine the pattern formed in the photopatternable material on the semiconductor substrate 400, and the pattern of the photopatternable material may, in turn, determine the pattern of isolated trenches subsequently formed on the semiconductor substrate 400. The isolated trenches may be filled with a conductive material to form lines on the semiconductor substrate 400. Alternatively, the isolated trenches may be used in a damascene process. The semiconductor substrate may be further processed by conventional techniques to produce memory devices including, but not limited to, a NAND FLASH device, a dynamic random access memory (“DRAM”) device, a logic device, or other semiconductors devices. The memory or other semiconductor device may be used in wireless devices, personal computers, or other electronic devices, without limitation.

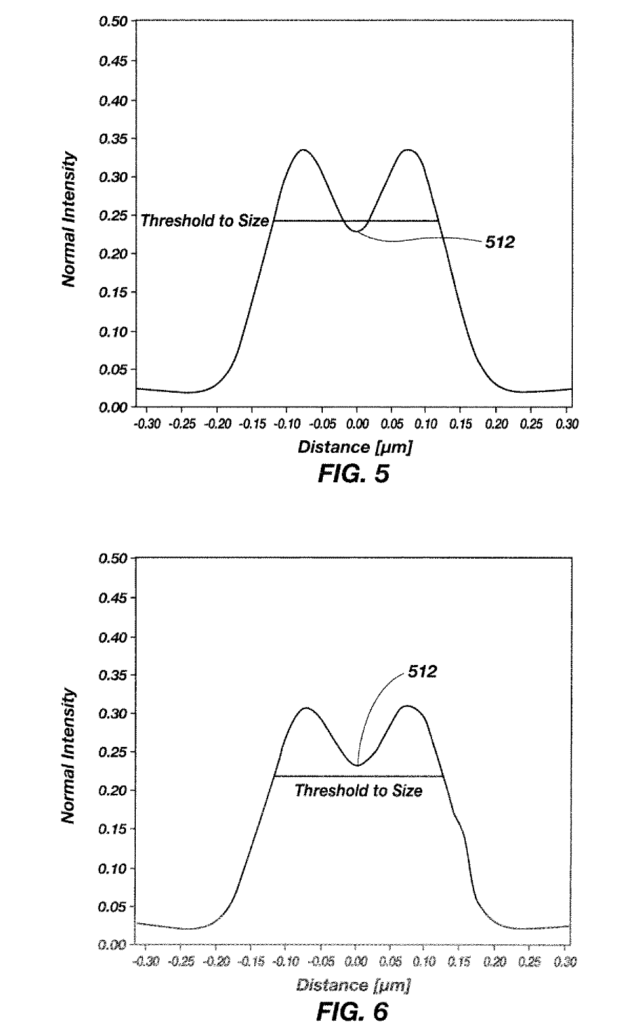

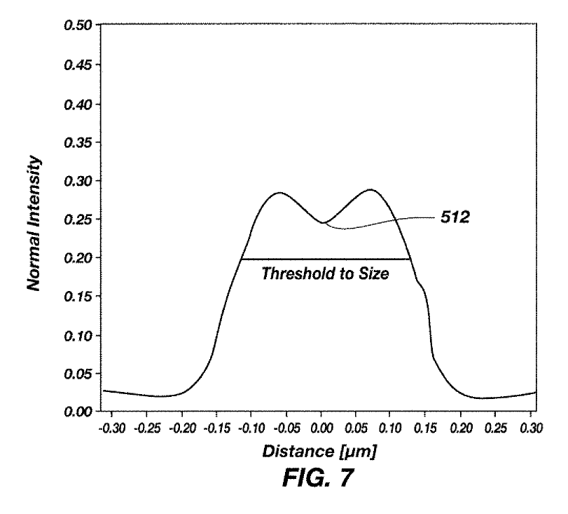

Three-dimensional mask optical simulations of a conventional isolated trench were conducted using a control reticle and reticle 100′. Changes in light intensity (y-axis) versus the width of the isolated trench (x-axis) are shown in FIG. 5 for the control reticle and in FIGS. 6 and 7 for the reticle 100′. The control reticle lacked the assistant structure 130, while the reticle 100′ included a 5 nm assistant structure 130 formed from Cr (FIG. 6) or a 10 nm assistant structure 130 formed from Cr (FIG. 7). Expect for the differences between the control reticle and the reticle 100′, the isolated trenches were formed using identical illumination conditions: the illumination source was a dipole 60° with 0.96/0.76 partial coherence, the numerical aperture of the projection lens pupil was 0.85, and the illumination wavelength was 193 nm. The isolated trenches had a 240 nm trench width. As shown in FIGS. 5-7, the tight intensity varied across the isolated trench and included a dimple 512 in the middle of the isolated trench. If the drop in light intensity falls below a threshold to size level, which is indicated on FIGS. 5-7, at more than two points, defects or scumming in the isolated trench may occur. The threshold to size level is defined as a light intensity level at which reticle features are resolved on a pre-designed semiconductor substrate (drawn size or drawn critical dimension). As shown in FIG. 5, the light intensity dropped below the threshold to size level at dimple 512, giving rise to a potential underexposure within the isolated trench. This potential underexposure is believed to result in defects or scumming in the isolated trench when using the control reticle because the photopatternable material on the semiconductor substrate may not be fully exposed and, therefore, is not fully developed. However, as shown in FIGS. 6 and 7, the light intensity remained above the threshold to size level at dimples 512 using the reticle 100′ having the assistant structure 130. As such, isolated trenches formed using the reticle 100′ with the assistant structure 130 should produce reduced scumming. Similar results are also expected if reticle 100″, reticle 100′″, or reticle 100″″ is used to form the isolated trenches.

To provide further reductions in scumming, the reticle 100 including the assistant structure 130 may be used in combination with other known structural approaches for reducing scumming, such as those described in U.S. patent application Ser. No. 11/670,887 entitled “Phase Shift Mask With Two-Phase Clear Feature” and filed on Feb. 2, 2007, and U.S. patent application Ser. No. 11/756,307 entitled “Apparatus and Method For Defect-Free Microlithography” and filed on May 31, 2007, the disclosure of each of which is incorporated by reference herein in its entirety.

Since the assistant structure 130 may be formed on the reticle 100 by conventional techniques, the reticle 100 may be readily formed without the additional of costly and time-consuming acts to the overall process of fabricating the reticle 100. In addition, the various embodiments of the invention enable variation in reticle design, as well as variation in selection of the illumination source that may be used. Previous attempts to limit scumming in printed isolated trenches included limiting the design of the reticle such that no isolated trenches were printed on the semiconductor substrate in a preferred direction. In addition, it was found that using a dipole source as the illumination source provided reduced scumming in the preferred direction. However, using the dipole source place limits on the illumination source that may be used and requires knowledge well in advance of preparing the reticle of what type of illumination source is to be used. In other words, the reticle has to be designed with a specific illumination source in mind. Since the reticles of the invention may be used to print isolated trenches in the preferred direction without regard for the illumination source, the reticles of the invention provide increased flexibility.

While the invention will be recognized by those of ordinary skill in the art as susceptible to various modifications and alternative forms, specific embodiments have been shown by way of example in the drawings and have been described in detail herein. However, it should be understood that the invention is not intended to be limited to the particular forms disclosed. Rather, the invention includes all modifications, variations, and alternatives falling within the scope of the invention as encompassed by the following appended claims and their legal equivalents.

What is claimed is:

1. A reticle, comprising:
an optically transparent material, a phase shift and transmission control material in contact with the optically transparent material, and an assistant structure, the assistant structure comprising an absorptive material in contact with at least sidewalls of the phase shift and transmission control material.

2. The reticle of claim 1, wherein the absorptive material comprises chromium, a chromium-containing compound, titanium nitride, tungsten, or combinations thereof.

3. The reticle of claim 1, wherein the absorptive material contacts an exposed horizontal edge of the optically transparent material.

4. The reticle of claim 1, wherein the absorptive material contacts sidewalls of the optically transparent material.

5. The reticle of claim 1, wherein the absorptive material contacts an exposed bottom edge of the optically transparent material.

6. A reticle, comprising:
a phase shift and transmission control material formed on an optically transparent material, the phase shift and transmission control material comprising a gap defined by sidewalls of the phase shift and transmission control material; and
an assistant structure on at least the sidewalls of the phase shift and transmission control material.

7. The reticle of claim 6, further comprising a trench in the optically transparent material.

8. The reticle of claim 7, wherein the trench in the optically transparent material is centered to the gap in the phase shift and transmission control material.

9. The reticle of claim 7, wherein a width of the trench is between approximately 25% and approximately 50% of a width of the gap.

10. The reticle of claim 7, wherein the assistant structure contacts sidewalls of the optically transparent material.

11. The reticle of claim 7, wherein the assistant structure lines the gap in the phase shift and transmission control material and the trench in the optically transparent material.

12. The reticle of claim 6, wherein the assistant structure has a thickness of from approximately 10 nm to approximately 40 nm.

13. A method of forming a reticle, comprising:
producing a gap in a phase shift and transmission control material formed on an optically transparent material, the gap exposing an edge of the optically transparent material; and
forming an absorptive material on sidewalls of the phase shift and transmission control material and the edge of the optically transparent material.

14. The method of claim 13, wherein forming an absorptive material on sidewalls of the phase shift and transmission control material and the edge of the optically transparent material comprises forming an optically opaque material on the sidewalls.

15. The method of claim 13, wherein forming an absorptive material on sidewalls of the phase shift and transmission control material and the edge of the optically transparent material comprises conformally depositing the absorptive material on the sidewalls of the phase shift and transmission control material and the edge of the optically transparent material.

16. The method of claim 15, wherein conformally depositing the absorptive material on the sidewalls of the phase shift and transmission control material and the edge of the optically transparent material comprises conformally depositing chromium, a chromium-containing compound, titanium nitride, tungsten, or combinations thereof on the sidewalls and edge.

17. The method of claim 13, further comprising removing the absorptive material from the edge of the optically transparent material.

18. A method of forming a reticle, comprising:
forming an opening in a photodefinable material on a phase shift and transmission control material disposed on an optically transparent material;
transferring the opening into the phase shift and transmission control material to produce a gap therein;
removing the photodefinable material;
forming another photodefinable material in the gap and over the phase shift and transmission control material;
forming another opening in the another photodefinable material;
transferring the another opening into the optically transparent material to produce a trench therein;
forming an absorptive material on sidewalls of the phase shift and transmission control material, a horizontal edge of the optically transparent material, sidewalls of the optically transparent material, and a bottom edge of the optically transparent material; and
removing the another photodefinable material to form an assistant structure in the gap and in the trench.

19. The method of claim 18, further comprising forming a width of the trench to comprise from approximately 25% to approximately 50% of a width of the gap.

20. The method of claim 18, further comprising removing the absorptive material from the horizontal edge and the bottom edge of the optically transparent material.

21. A method of forming at least one feature on a semiconductor substrate, comprising:
positioning a reticle comprising an assistant structure configured to absorb at least a portion of light emitted by the illumination source between an illumination source and a semiconductor substrate;
transmitting light from the illumination source to the reticle and absorbing at least a portion of the light with the assistant structure;
passing non-absorbed light through the reticle;
exposing a photopatternable material on the semiconductor substrate to the non-absorbed light; and
utilizing the exposed photopatternable material as a mask to form at least one feature in the semiconductor substrate.

22. The method of claim 21, wherein the assistant structure comprises an absorptive material in contact with at least sidewalls of a phase shift and transmission control material of the reticle.

23. The method of claim 22, wherein the assistant structure comprises an absorptive material in contact with at least sidewalls of an optically transparent material of the reticle.

24. The method of claim 21, wherein the assistant structure lines a gap in a phase shift and transmission control material of the reticle and a trench in an optically transparent material of the reticle.

25. The method of claim 21, wherein exposing a photopatternable material on the semiconductor substrate to the non-absorbed light comprises exposing the photopatternable material to the non-absorbed light at above a threshold to size level.
